(19) United States
(12) Patent Application Publication
(10) Pub. No.: US 2013/0220797 A1
(43) Pub. Date: Aug. 29, 2013

(54) HIGH TARGET UTILIZATION MOVING MAGNET PLANAR MAGNETRON SCANNING METHOD

(71) Applicant: Phong Ngo, Tucson, AZ (US)

(72) Inventor: Phong Ngo, Tucson, AZ (US)

(73) Assignee: GENERAL PLASMA, INC., Tucson, AZ (US)

(21) Appl. No.: 13/816,990

(22) PCT Filed: May 19, 2011
(86) PCT No.: PCT/US11/37075

§ 371 Date: Feb. 14, 2013

(30) Foreign Application Priority Data
May 19, 2010 (US) 61346158

(51) Int. Cl. C23C 14/35; C23C 14/34

(52) U.S. Cl. CPC C23C 14/35; C23C 14/3407
USPC 204/192.12; 204/298.12

(57) ABSTRACT

A method for operating a moving magnet magnetron is provided enhanced target utilization. A magnet pack is moved in a first 2-D motion profile with a variable velocity. The magnet pack is then translated in a second 2-D motion profile that varies relative to the first profile. This process moving and translating is repeated to provide enhanced target utilization. These varied movement and translation profiles preclude the formation of a diamond-shaped erosion area common to the prior art. Representative to such profiles are intersecting sigmoidal curves. The resultant target is characterized by a metal from that has better target utilization as the wear pattern precludes the diamond shaped erosion area common to the prior art and instead has a multiple erosion peaks.

### RELATED APPLICATIONS

This application claims priority benefit of U.S. Provisional Application No. 61/346,158 filed May 19, 2010; the contents of which are hereby incorporated by reference.

### BACKGROUND

1. Field of the Invention

The present invention relates generally to magnetron sputtering and, in particular, to scanning methods for moving magnet planar magnetrons to improve the target utilization.

2. Background of the Invention

Moving magnet planar magnetron (MMPM) sputtering is well known in the art. FIG. 1 and FIG. 1A show a prior art 2-axis moving magnet planar magnetron 26 with sputter racetrack 4 on the outer surface of the planar target 1. The magnet pack 20 has the ability to move within the planar magnetron housing 25 during sputtering operation that moves the sputter racetrack erosion area 4 on planar target 1. This movement results in an increase of the effective target erosion area and hence increases the overall target utilization.

MMPMs move the magnet pack to distribute the wear over a larger area relative to static magnet pack magnetrons. Ideally an MMPM should operate such that the magnet pack spends approximately the same amount of time in each unit area. However, this ideal is especially difficult to achieve at the magnetron turn-around region 3, because as the magnet pack is moved under the target, the arc geometry of the turn-around crosses over itself at the center region. This creates a diamond-shaped area 6 of higher rate erosion, FIG. 2. Consequently the sputter target is worn through at this diamond-shaped area 6 prematurely, reducing the overall target utilization. While several prior art attempts have been made to mitigate this effect, these attempts have met with limited success based on the weight percent of target utilization being at most about 48%. The prior art MMPMs are limited by premature target wear in the turn-around region 3 of planar target 1. An example of this premature turn-around wear is shown in FIG. 2. This is a photographic image of an actual eroded target that shows the “diamond shape” deep erosion area 6 that forms as a groove in turn-around region 3.

FIG. 3 shows prior art scanning paths for a magnet pack that adjust the relative speed ratio between the two motion axes. The selection of relative magnet pack speed ratios creates denser scanning paths within the movement area. FIG. 4 and FIG. 5 show 2-D and 3-D views, respectively, of mathematical models of the target erosion when any of these prior art motion profiles are used. As can be seen, all these scanning profiles result in extra target erosion at the diamond area. The mathematical model erosion profile is verified in actual target erosion in FIG. 2.

There are several prior art patents that propose different methods to improve target utilization of moving magnet planar magnetrons. In U.S. Pat. Nos. 6,322,679 and 6,416,639, De Bosscher discloses several repetitive magnet pack motion profiles relative to the planar target that include circular, ellipse, oval, egg shape, epitrochoidal or hypotrochoidal shape. In U.S. Patent Application Publication US 2006/0049040, Tepman proposes several scanning methods for two-dimensional magnetron sputtering onto flat panels mainly to increase erosion area including diagonal scan, double-Z scan path, sequence of offset double-Z scans, serpentine scan path, zigzag diagonal scan path, and figure-8 scan path. These prior art methods use single motion profiles that still suffer from the “diamond shape” erosion groove area 6 phenomena.

Thus, there exists the need for a scanning method that provides enhanced target modifies the diamond erosion area observed in conventional MMPMs to thereby improve utilization in moving magnet planar magnetrons.

### SUMMARY OF THE INVENTION

A method for operating a moving magnet magnetron is provided enhanced target utilization. A magnet pack is moved in a first 2-D motion profile with a variable velocity. The magnet pack is then translated in a second 2-D motion profile that varies relative to the first profile. This process moving and translating is repeated to provide enhanced target utilization. These varied movement and translation profiles preclude the formation of a diamond-shaped erosion area common to the prior art. Representative to such profiles are intersecting sigmoidal curves. The resultant target is characterized by a metal from that has better target utilization as the wear pattern precludes the diamond shaped erosion area common to the prior art and instead has a multiple erosion peaks.

### BRIEF DESCRIPTION OF THE DRAWINGS

FIG. 1 shows a prior art structure of a 2-dimensional moving magnet planar magnetron.

FIG. 1A shows a prior art section side view of the MMPM of FIG. 1.

FIG. 2 shows a prior art actual target erosion at turn around region of when a prior art scanning method is used.

FIG. 3 shows repetitive uniform prior art wear motion profiles at different speed ratios of the two motion axis.

FIG. 4 shows 2-D view of a mathematical model of the target erosion pattern at the turn-around when a prior art scanning method is used.

FIG. 5 shows 3-D view of a mathematical model of the target erosion pattern at the turn-around when a prior art scanning method is used.

FIG. 6 shows an inventive butterfly motion profile.

FIG. 7 shows 2-D view of the mathematical model of the target erosion pattern using the inventive butterfly motion profile.

FIG. 8 shows 3-D view of the mathematical model of the target erosion pattern using the inventive butterfly motion profile.

FIG. 9 shows an inventive dual-circulation motion profile.

FIG. 10 shows an inventive dual-diagonal ellipse motion profile.

FIG. 11 shows 2-D view of mathematical model of the target erosion pattern using the present invention motion profile.

FIG. 12 shows 3-D view of mathematical model of the target erosion pattern using the present invention motion profile.

FIG. 12A shows actual target erosion at turn-around region when present invention scanning method is used.

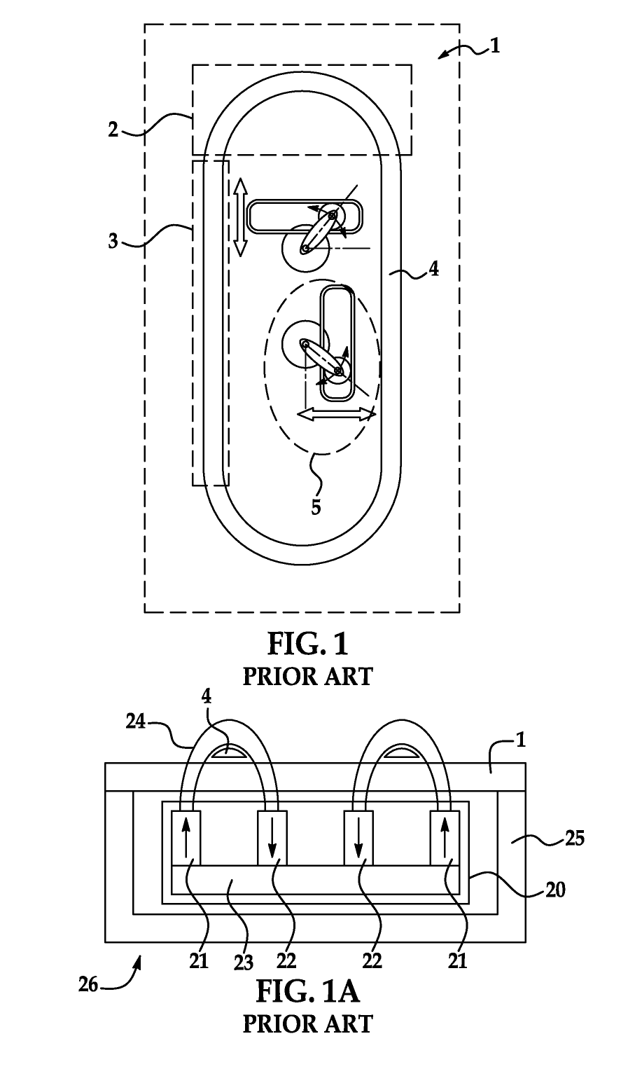

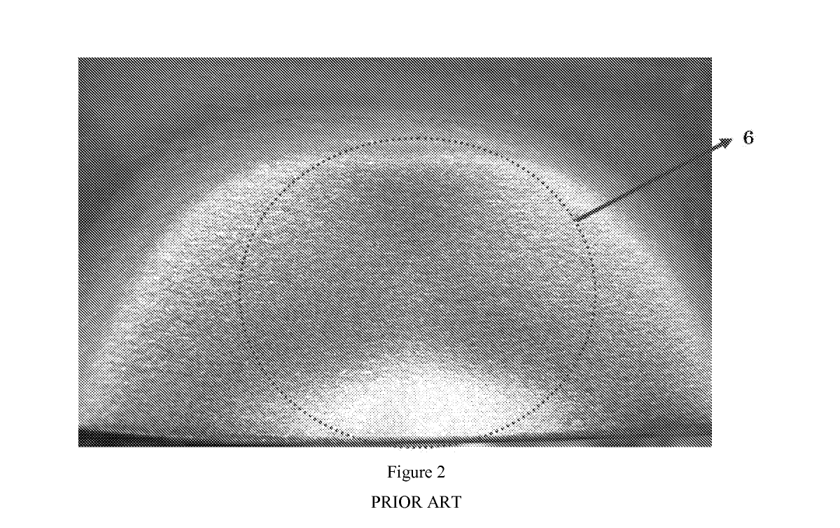

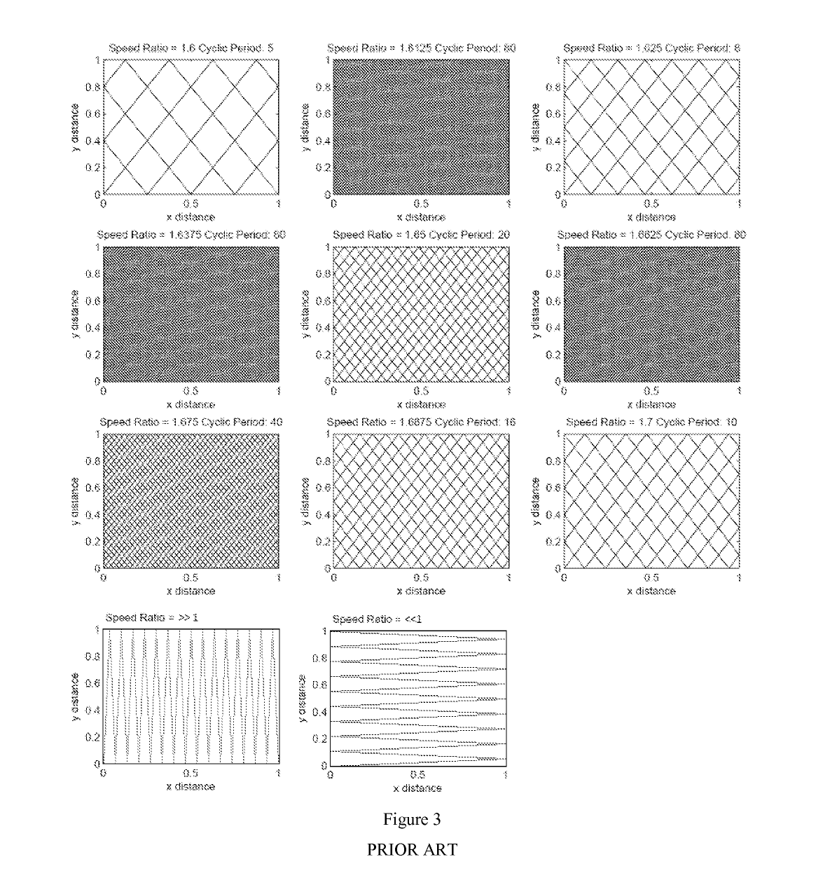

### DETAILED DESCRIPTION OF THE PREFERRED EMBODIMENTS

The present invention has utility in increasing target utilization of a moving magnet planar magnetron (MMPM). The present invention provides a novel method of magnet pack scanning that combines multiple magnet motion profiles to produce non-overlapping motion paths over the deepest erosion groove locations of a target.

To improve target utilization and avoid a premature wear groove or spot, an inventive magnet pack motion profile spreads the target erosion area over a larger area relative to conventional MMPMs while target wear remote from deepest erosion groove locations is comparatively unchanged. The present invention introduces a novel magnet pack scanning method that overcomes premature wear in the diamond area. The inventive scanning method involves moving the magnet pack at constant linear speed on 2-D perpendicular axes and varying the speed ratio between the two axes to afford non-overlapping motion paths.

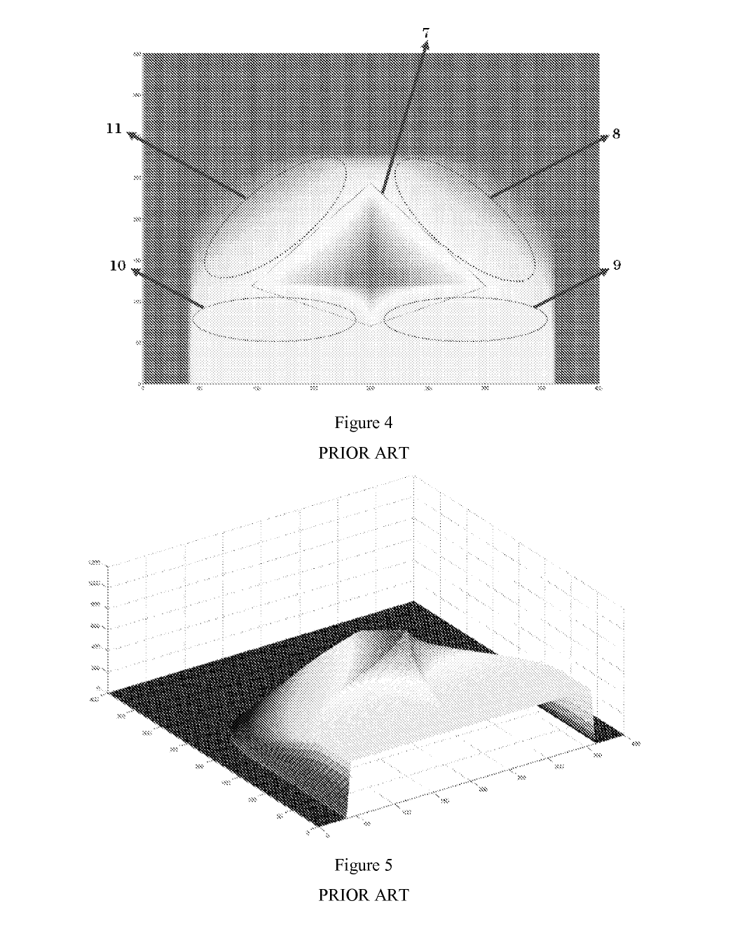

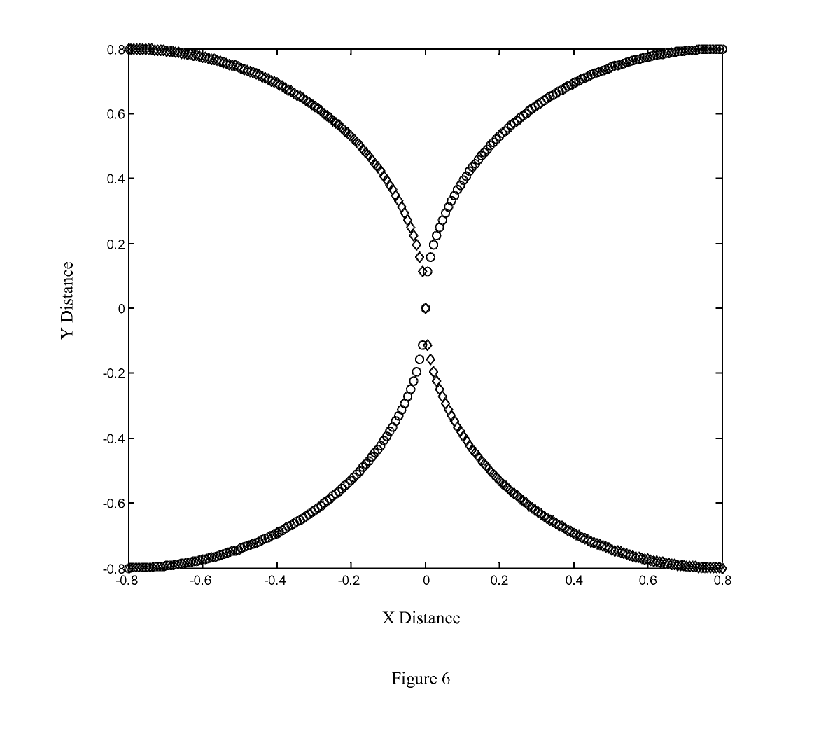

The present invention generates localized target erosion in regions 8, 9, 10 and 11 around “diamond shape” region 7, where regions 8-11 are depicted in FIG. 4. These localized target erosion regions are achieved using the butterfly (intersecting sigmoidal curve) motion profile as shown in FIG. 6. Each circle or diamond on FIG. 6 represents a reference location of magnet pack within the magnet pack movement area separated by equal amounts of time.

Increased magnet pack velocity is noted as the magnet pack approaches the point of inflection region. With less dwell time in the region at, and around the point of inflection in the sigmoid curves (circles and diamonds), wear otherwise defining the prior art “diamond” wear pattern is spread into the regions adjacent to each side of the “diamond” pattern denoted at numerals 8, 9, 10, and 11. A point of inflection is defined herein as a point on a magnet pack motion profile as a function of time where the double derivative (acceleration) is zero and bounded by non-zero values. By spreading the wear into the regions that would otherwise be adjacent to at least two side, and preferably, four sides of the conventional diamond-shaped erosion area through motion profiles to non-overlapping locations of the deepest erosion grooves, overall utilization of a sputter target is increased. The inventive wear patterns are shown in illustrative form for non-overlapping movement patterns in FIGS. 6-12.

“Moving” and “translating” along with the noun forms of “motion” and “translation” are used synonymously throughout the application. “Variable” and “non-constant” are used synonymously throughout the application.

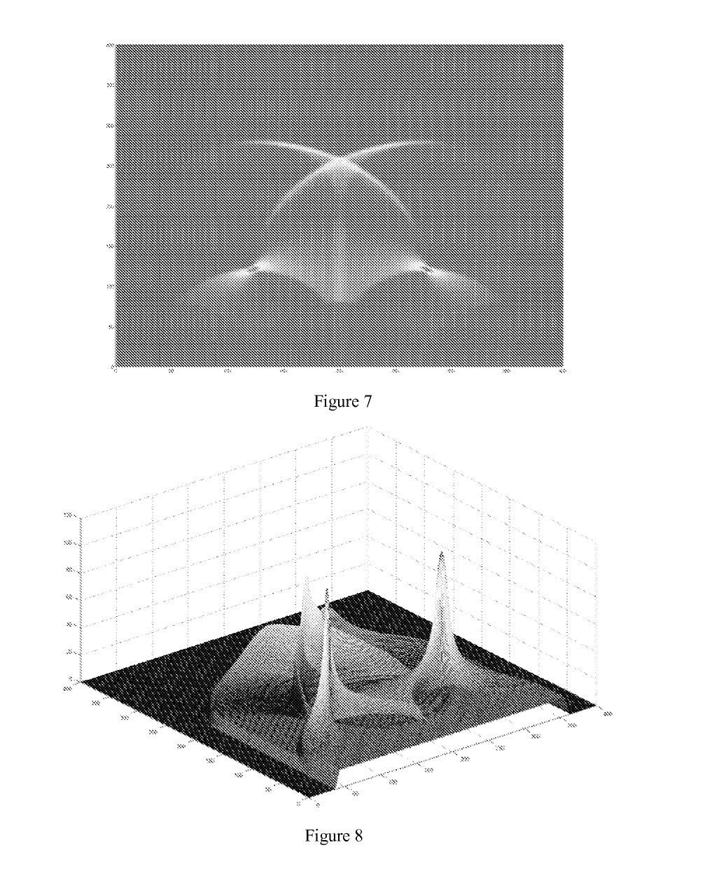

FIG. 7 and FIG. 8 show the 2-D and 3-D views, respectively, of the resulting target erosion pattern using the inventive butterfly (intersecting sigmoidal curve) scanning method. As shown in FIG. 7 and FIG. 8, this butterfly motion profile successfully distributes target erosion into adjacent regions outside the diamond area.

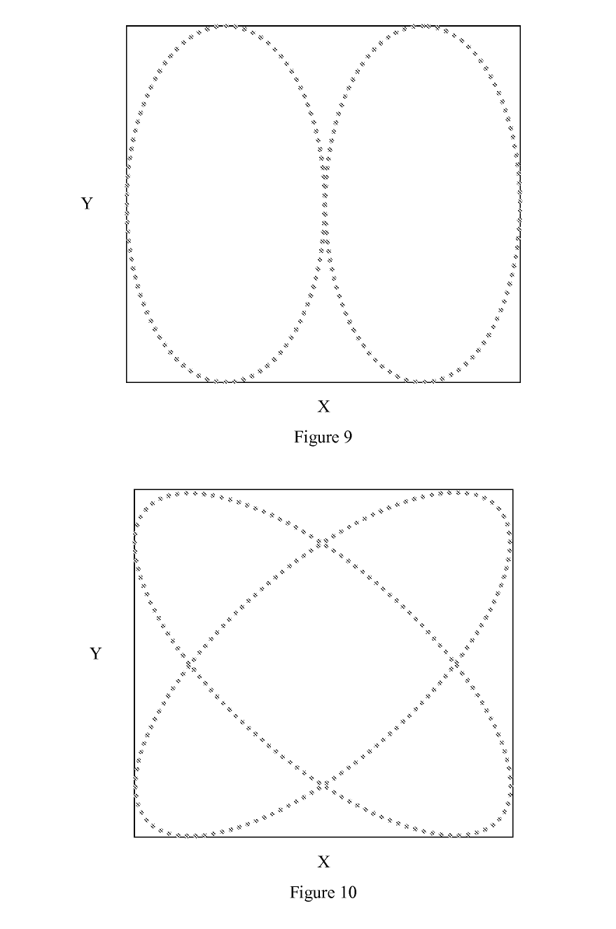

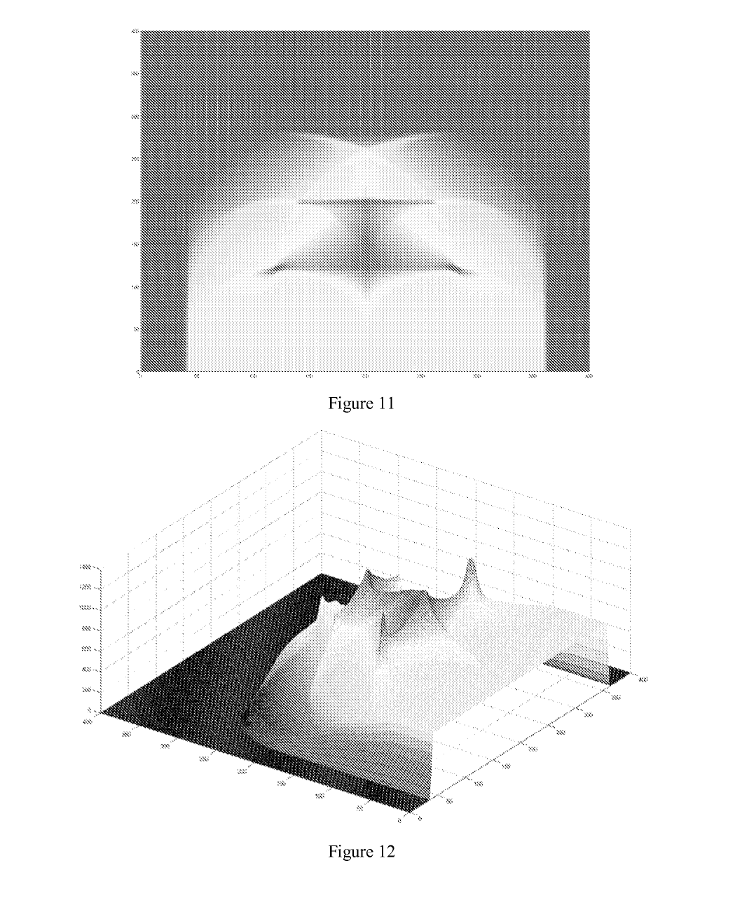

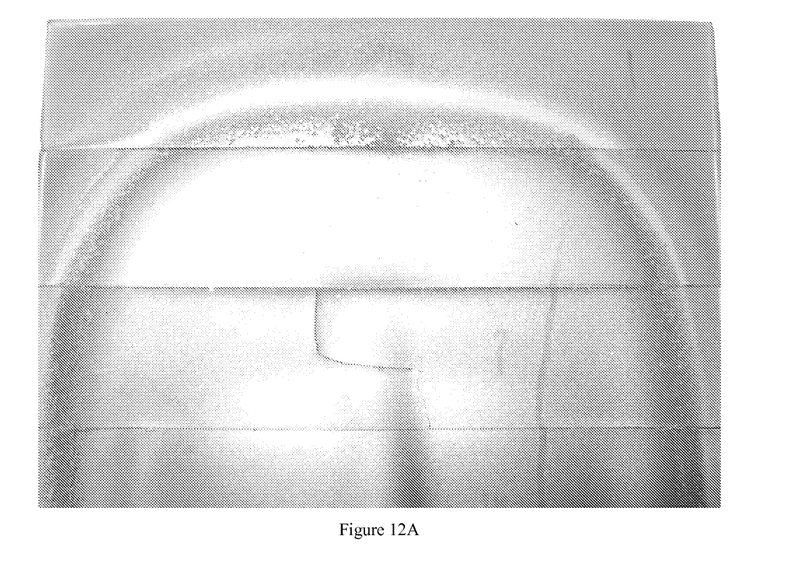

FIGS. 9 and 10 show variations of the butterfly motion profile that achieve similar localized target wear regions with intersecting ellipsoid magnet pack motion profiles. For visual clarity the dots defining the magnet pack motion in FIGS. 9 and 10 are not temporally spaced and as such do not reflect velocity changes associated with points of inflection. It is appreciated that in addition to two intersection ellipsoidal or sigmoidal motion profiles, three or more such tracks or a combination of sigmoidal and ellipsoidal paths are readily combined. In a preferred embodiment, the inventive erosion pattern has a plane of symmetry with a least one off-plane erosion area, as shown for example, at coordinates (125, 100),(125, 300) in FIG. 8; and (175, 175), (175, 350) in FIG. 12. Still more preferably, a mirror plane exists between the deepest erosion features with the appreciation that the actual shape and dimensions of the off-plane erosion area peaks vary in depth, exact position, and profile from the theoretical simulation of an erosion profile. The target erosion peaks define novel wear patterns such as three displaced points of maximal erosion forming a triangular wear pattern, as shown in FIGS. 7 and 8; and a T-shaped wear pattern, as shown in FIGS. 11 and 12.

According to the present invention, multiple parabolic, sigmoidal, ellipsoidal or a combination of such motion profile non-overlapping locations of the deepest erosion grooves and thereby improve the overall utilization of a sputter target. Preferably, the velocity of magnet pack motion varies around a motion profile and more preferably, has no acceleration at a point of inflection. Optionally, combining multiple motion profiles, the relative cyclic ratio between these multiple profiles is controlled such that target utilization is optimized. FIGS. 11 and 12 show 2-D and 3-D views of the target erosion pattern when three repetitive motion profiles are sequentially performed per FIGS. 6, 9 and 10, along with one that just scanning with constant speed in one direction. Significant wear improvement is observed in the turn-around region for this inventive magnet pack scanning motion as shown in FIG. 12A. FIG. 12A is a picture of an actual eroded target that shows no sign of a “diamond” deep erosion groove but rather a desired uniform target wear in turn-around region.

Using the inventive method of combining multiple magnet pack motion profiles, target utilization is increased by more than 18 target weight percent, between 18 and 25 percent, and even more than 25 percent. When an inventive method is implemented in an actual moving magnet planar magnetron, the measured target utilization is 70% per FIG. 12A and exceeds the 48% of a conventional MMPM.

While the present invention has been illustrated and described as embodied in an exemplary embodiment, e.g. an embodiment having particular utility unplugging drains, it is to be understood that the present invention is not limited to the details shown herein, since it will be understood that various omissions, modifications, substitutions and changes in the forms and details of the disclosed cleaning apparatus and its operation may be made by those skilled in the art without departing in any way from the spirit and scope of the present invention.

Patents and publications mentioned in the specifications are indicative of the levels of those skilled in the art to which the invention pertains. These patents and publications are incorporated herein by reference to the same extent as if each individual application or publication was specifically and individually expressed explicitly in detail herein.

1. A method for operating a moving magnet magnetron to provide enhanced target utilization comprising:
moving a magnet pack in a first 2-D motion profile, said first motion profile having a variable velocity;
translating the magnet pack in a second 2-D motion profile that varies relative to the first profile;
repeating the moving and the translating steps to provide enhanced target utilization.

2. The method of claim 1 wherein said first motion profile is a pair of 2-D intersecting sigmoidal curves forming a butterfly pattern.

3. The method of claim 2 wherein the butterfly pattern has zero acceleration at a point of inflection thereof

4. The method of claim 1 wherein said second motion profile has a non-constant velocity.

5. The method of claim 1 wherein the repeating step varies a ratio between said first motion profile and said second motion profile.

6. The method of claim 1 wherein the enhanced target utilization has a diamond pattern and additional wear proximal to at least one side of the diamond pattern.

7. The method of claim 1 wherein the first motion profile has the variable velocity such that said magnet pack spends approximately an equal amount of time at each location within said target and across a substrate transfer direction.

8. The method of claim 7 wherein the variable velocity varies by a factor of two or more times faster or slower than a substrate traveling relative to the magnetron.

9. The method of claim 1 wherein the first motion profile and repeating the first motion profile is such that said magnet pack spends approximately equal amounts of time at each unit area of travel.

10. The method of claim 1 further comprising moving said magnet pack in a third 2-D motion profile, said third motion profile having a variable velocity and repeating the third 2-D motion profile moving step.

11. A sputtering target formed by the method of claim 1 comprising a metal form having a sputter induced wear pattern having a plurality of erosion peaks.

12. The target of claim 11 wherein said plurality of erosion peaks are symmetrical around a symmetry axis.

13. The target of claim 12 wherein said plurality of erosion peaks are displaced from the axis.

14. The target of claim 12 wherein said plurality of erosion peaks define at least two displaced points of maximal erosion.

15. The target of claim 12 wherein said plurality of erosion peaks define three displaced points of maximal erosion forming a triangular wear pattern.

16. The target of claim 12 wherein said plurality of erosion peaks define three displaced points of maximal erosion forming a T-shaped wear pattern.
